(19) United States
(12) Patent Application Publication
(10) Pub. No.: US 2005/0104142 A1
(43) Pub. Date: May 19, 2005

(54) CVD tantalum compounds for FET get electrodes

(76) Inventors: Vijav Narayanan, New York, NY (US); Fenton R. McFeely, Ossining, NY (US); Keith Raymond Milkove, Beacon, NY (US); John Jacob Yurkas, Stamford, CT (US); Matthew Warren Copel, Yorktown Heights, NY (US); Paul Charles Jamison, Hopewell Junction, NY (US); Roy A. Carruthers, Stormville, NY (US); Cyril Cabral JR., Ossining, NY (US); Edmund M. Sikorskii, Florida, NY (US); Elizabeth A. Duch, North Salem, NY (US); Alessandro C. Callegari, Yorktown Heights, NY (US); Sufi Zafar, Briarcliff Manor, NY (US); Kazuhito Nakamura, Nagoya-shi (JP)

Correspondence Address: George Sai-Halasz, 145 Fernwood Dr., Greenwich, RI, 02818, US

(21) Appl. No.: 10/712,575

(22) Filed: Nov. 13, 2003

(51) Int. Cl. H01L 29/76

(52) U.S. Cl. 257/412; 438/582

(57) ABSTRACT

Compounds of Ta and N, potentially including further elements, and with a resistivity below about 20 mΩcm and with the elemental ratio of N to Ta greater than about 0.9 are disclosed for use as gate materials in field effect devices. A representative embodiment of such compounds, TaSiN, is stable at typical CMOS processing temperatures on SiO₂ containing dielectric layers and high-k dielectric layers, with a workfunction close to that of n-type Si. Metallic Ta—N compounds are deposited by a chemical vapor deposition method using an alkylimidotris(dialkylamido)Ta species, such as tertiaryamylimidotris(dimethylamido)Ta (TAIMATA), as Ta precursor. The deposition is conformal allowing for flexible introduction of the Ta—N metallic compounds into a CMOS processing flow. Devices processed with TaN or TaSiN show near ideal characteristics.

### FIELD OF THE INVENTION

The present invention relates to a new class of gate materials for field effect transistors allowing better device properties and expanded device choices in the deeply submicron regime. More specifically, the invention teaches MOS gates formed with metallic tantalum-nitrogen compounds.

### BACKGROUND OF THE INVENTION

Today's integrated circuits include a vast number of devices. Smaller devices are key to enhance performance and to improve reliability. As MOSFET (Metal Oxide Semiconductor Field-Effect-Transistor, a name with historic connotations meaning in general an insulated gate Field-Effect-Transistor) devices are being scaled down, the technology becomes more complex and new methods are needed to maintain the expected performance enhancement from one generation of devices to the next.

Some of the requirements for the gate of a MOSFET are the following: it has to be a conductor; it has to fit into a device fabrication process, namely that it can be deposited and patterned, and be able to withstand the many processing steps involved in device fabrication; it has to form a stable composite layer with the gate dielectric, namely not to cause harm to the dielectric during the many processing steps involved in device fabrication; yield threshold voltages required for proper operation of the devices and circuits, typically CMOS circuits. The mainstay gate material of silicon (Si) based microelectronics is the highly doped polycrystalline Si (poly). The requirements for proper threshold voltage in advanced CMOS circuits are such that the PMOS device needs p⁺-poly and the NMOS needs n⁺-poly. This is due to considerations related to matching the workfunction of the gate material to that of the device body material. However, the poly gate approach will not facilitate aggressive scaling and would result in an increasing number of problems in future miniaturized devices.

### SUMMARY OF THE INVENTION

In view of the problems discussed above there is a need for novel gate materials which fulfill the requirements of advanced present day, and future further down-scaled devices. This invention discloses a materials, and a method for fabrication, that fulfill the requirements of advanced gate materials. More specifically, a disclosed material is suitable as gate material in NMOS devices.

The disclosed materials are the compounds having Ta and N, such as TaN or TaSiN. (Ta being the elemental symbol of tantalum, and N of nitrogen, and Si of silicon.) These materials have been known and used for a variety of purposes. Typically they have been deposited by physical vapor deposition (PVD) techniques, such as sputtering. When in the prior art chemical vapor deposition (CVD) was used, it was done with halide based Ta precursors and activated nitrogen (using a plasma) for deposition of TaN. It is known that both Cl and especially F can degrade gate dielectrics in MOS devices. In addition, plasma processes can also result in damage to the gate dielectric. Alternative prior art CVD techniques, using various metal organic Ta precursors with ammonia, in most cases resulted in the deposition of Ta₃N₅, an insulator.

This invention contemplates a CVD process where an alkylimidotris(dialkylamido)Ta species is used for Ta precursor in the CVD process. Representative members of the of the species are, for instance, tertiaryamylimidotris(dimethylamido)Ta (TAIMATA) and (t-butylimido)tris(diethylamido)Ta. This CVD process leads to stoichiometrically balanced TaN compounds resulting in a metallic materials. Additionally with the further introduction of Si, the TaSiN compound is not only metallic but has a workfunction suitable to use with NMOS devices. The disclosed CVD process also results in conformal layers, allowing deposition on patterned wafer surfaces in contrast to the directional nature of various PVD processes.

### BRIEF DESCRIPTION OF THE DRAWINGS

These and other features of the present invention will become apparent from the accompanying detailed description and drawings, wherein:

FIG. 1 shows an X-ray Theta-2 Theta diffraction of a CVD TaN layer;

FIG. 2 shows an X-ray Theta-2 Theta diffraction of a CVD TaSiN layer;

FIG. 3 shows elemental ratios of Si and N in TaSiN, where Ta is normalized to 1;

FIG. 4 shows 100 kHz C—V curves with a TaN layer electrode using a 2.6 nm oxide insulator;

FIG. 5 shows workfunction derivation for a TaN electrode using a flatband voltage versus equivalent oxide thickness plot;

FIG. 6 shows C—V curves of TaSiN electrodes having different Si contents;

FIG. 7 shows workfunction derivation for a TaSiN electrode using a flatband voltage versus equivalent oxide thickness plot;

FIG. 8 shows workfunction derivation for a TaSiN electrode using tunneling current;

FIG. 9 shows I_{d}—V_{g} curves in and FET using a TaSiN gate electrode and a high-k gate dielectric;

FIG. 10 shows a schematic cross sectional view of a semiconductor field effect device having a metallic Ta—N compound gate;

FIG. 11 shows a symbolic view of a processor containing at least one chip which contains a semiconductor field effect device having a metallic Ta—N compound gate.

### DETAILED DESCRIPTION OF THE INVENTION

A chemical vapor deposition (CVD) processes have been developed for producing metallic tantalum (Ta)-nitrogen (N) compounds, such as TaN and TaSiN. In these processes an alkylimidotris (dialkylamido)Ta species, or material: tertiaryamylimidotris (dimethylamido)Ta (TAIMATA) was used as the Ta precursor. Ammonia (NH₃) served as the source for nitrogen (N) in the CVD deposition, while hydrogen H₂ was used for carrier gas. For one ordinarily skilled in the art it might be apparent that other materials could be substituted in the process for the ammonia and the hydrogen. With the tertiaryamylimidotris(dimethylamido)Ta (TAIMATA) and ammonia precursors and hydrogen carrier one obtains stoichiometric TaN, with a near 1:1 ratio of Ta to N, as determined by X-ray Photoelectron Spectroscopy (XPS). A N to Ta elemental ratio between about 0.9 and 1.1 gives layers for representative embodiments. The TaN films were deposited at a growth temperature between 400° C. and 550° C. and a chamber pressure ranging between 10-100 mTorr. The flow rates for the gases NH₃ and H₂ were in the range of 10-100 sccm.

FIG. 1 shows an X-ray Theta-2 Theta diffraction of a representative embodiment of the CVD deposited metallic TaN layer. The figure shows sharp crystalline peaks indicative of the cubic symmetry of the crystal as expected from the 1:1 stoichiometry. The two peaks in FIG. 1 correspond to the (111) and (200) peaks and are indicative of the cubic symmetry of TaN.

The CVD process developed in this invention can also yield metallic TaSiN. For this case tertiaryamylimidotris(dimethylamido)Ta (TAIMATA) was used as the Ta precursor, ammonia served as the source for N, and either silane (SiH₄) or disilane (Si₂H₆) were the precursors for silicon (Si), while hydrogen again was used as carrier gas.

The TaSiN films were deposited at a growth temperature between 400° C. and 550° C. and a chamber pressure ranging between 10-100 mTorr. The flow rates for the carrier gases of NH₃ and H₂ were in the range of 10-100 sccm. To incorporate Si in the films 5% Si₂H₆ or SiH₄ (by volume) was used with the flow rate varied between 5 and 100 sccm to obtain compositions such that the Si to Ta elemental ratio in TaSiN varies between 0.2 and 0.7

For one ordinarily skilled in the art it would be apparent that other materials could be substituted in the process for ammonia, silane, disilane, and hydrogen, for instance, using aminosilanes.

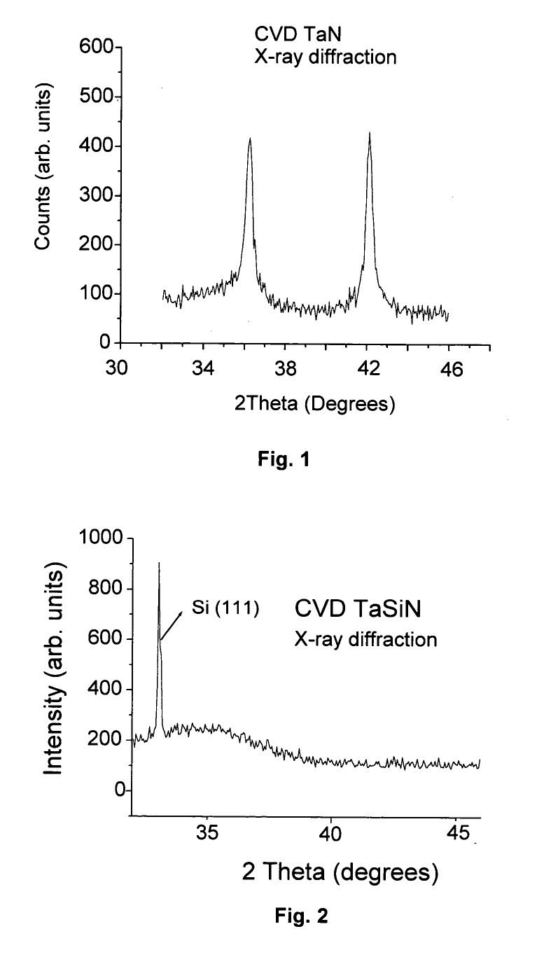

The addition of Si to TaN makes the compound amorphous (or finely polycrystalline) as shown in FIG. 2, in the X-ray Theta-2 Theta diffraction of a representative embodiment of the CVD deposited metallic TaSiN layer. The sharp peak marked “Si(111)” is due to the substrate underlying the TaSiN.

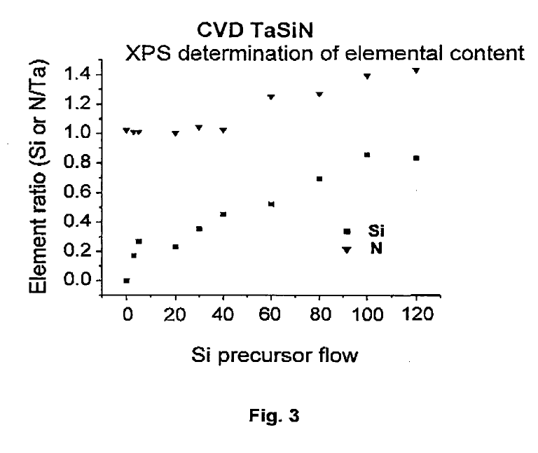

FIG. 3 shows elemental ratios of Si and N in TaSiN as measured by XPS. The elemental ratios, or concentrations, with the Ta concentration normalized to 1 are given as a function of the disilane Si precursor flow, with the growth temperature and other gas flows kept constant.

In general, one can contemplate gate materials in the metallic Ta—N compound family beyond TaN and TaSiN. Starting with a Ta precursor from the alkylimidotris(dialkylamido)Ta species one could form, for instance, TaGeN layers as well.

Conductivity measurements on representative embodiments of the CVD TaN layers give resistivity values below about 5 mΩcm. The TaSiN with an elemental Si content ratio between 0.35 and 0.5 yield conductivity values below about 20 mΩcm. (Resistivity is measured in units of ohm-centimeter (Ωcm), mΩcm stands for milliohm-centimeter, a thousandths of the ohm-centimeter.)

Electrical properties of the compounds having Ta and N were further investigated using Metal-Oxide-Semiconductor Capacitor (MOScap) structures. SiO₂ films were thermally grown on Si substrates, with varying thicknesses from about 2 nm to 5 nm, followed by blanket deposition of TaN or TaSiN. Sputter deposition of tungsten (W) through a shadow mask followed. Using the W as a hard mask, the Ta compound layers were etched away by reactive ion etching resulting in the MOScaps.

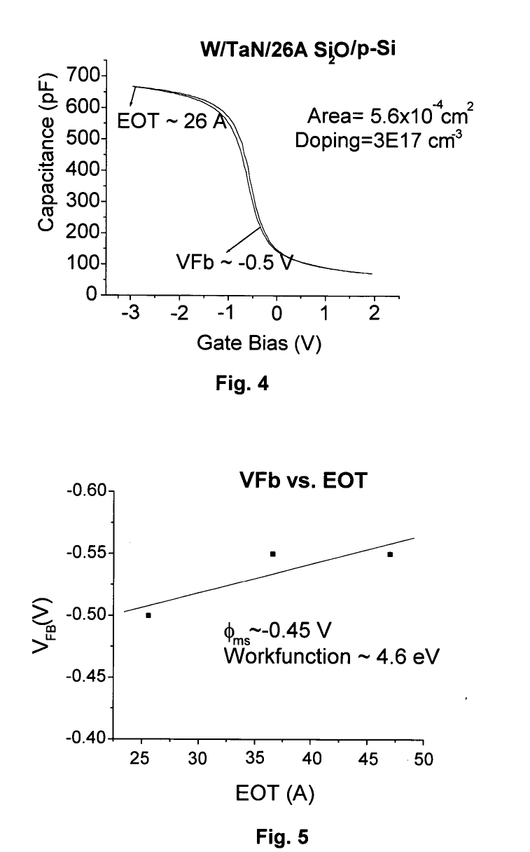

FIG. 4 shows 100 kHz C—V curves with a TaN layer electrode using a 2.6 nm oxide insulator. The excellent characteristics of the W/TaN/2.6 nm SiO₂/p-Si stack, clearly showing the depletion and accumulation characteristics, indicates that the TaN metallic layer cause no discernable damage to the 2.6 nm SiO₂ dielectric. The metallic TaN and the SiO₂ dielectric form a stable composite layer.

FIG. 5 shows workfunction derivation for a TaN electrode using a flatband voltage (V_{fb}) versus equivalent oxide thickness (EOT) plot, a technique known to those skilled in the art. The EOT refers to capacitance, meaning the thickness of such an SiO₂ layer which has the same capacitance per unit area as the dielectric layer in question. The TaN films exhibit a workfunction of ˜4.6 eV, which is slightly less than the Si midgap value (4.65 eV).

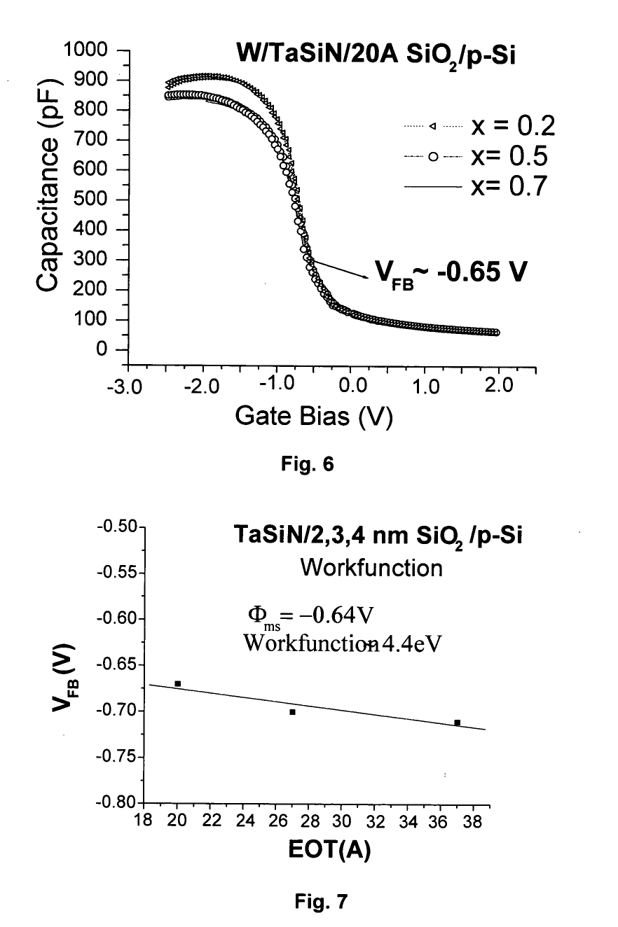

The addition of Si to the TaN compound makes the workfunction of the compound having Ta and N more like that of n-doped Si. FIG. 6 shows C—V curves of TaSiN electrodes having different Si contents. The metallic TaSiN and the 2 nm SiO₂ dielectric again form a stable composite layer, showing no discernable damage to the oxide. The C—V curves have near ideal characteristics in terms of their shape. In addition, these TaSiN films show a relatively large process window for optimization. As shown in FIG. 6, films grown with different Si contents, from 0.2 to 0.7, result in very similar V_{fb}. This suggests that from an ease of deposition point of view one has a robust process. A preferred range of Si content is between 0.35 and 0.5 of elemental concentration.

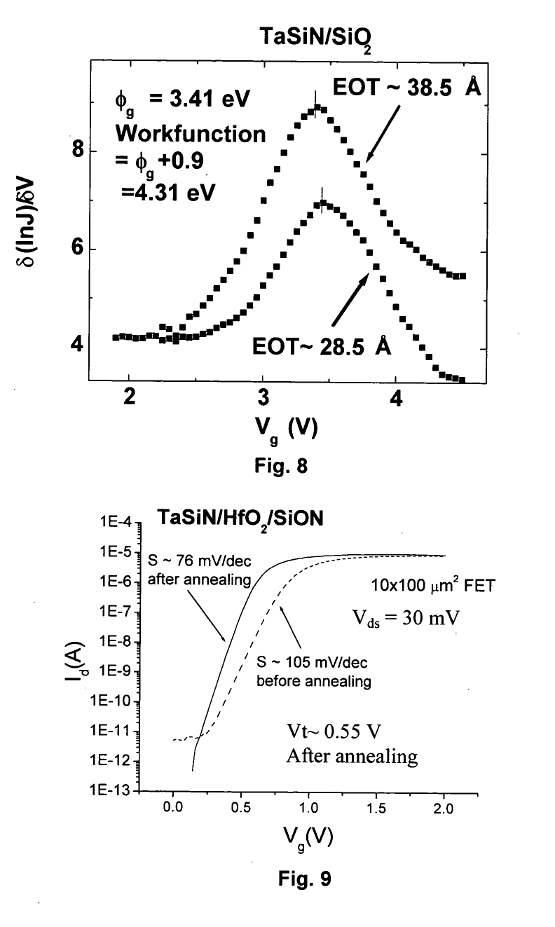

FIG. 7 shows workfunction derivation for a TaSiN electrode using a flatband voltage versus equivalent oxide thickness plot. The Si content for these electrodes is in the preferred range. These preferred TaSiN films have a workfunction of ˜4.4 eV as estimated from FIG. 7. The TaSiN workfunction was also obtained by a different and sensitive technique as shown in FIG. 8. As it is known in the art, measuring tunneling current as function of voltage can yield barrier height values. From these the workfunction can straightforwardly be obtained. The barrier height measurements shown in FIG. 8, indicate that TaSiN films have a ˜4.32 eV workfunction, in rough agreement with the flatband measurements. Both type of measurement techniques show CVD TaSiN to have a workfunction within 200-300 mV of n-poly workfunction of 4.1 eV. This makes the metallic TaSiN suitable as gate material for NMOS devices for advanced CMOS circuits.

There is a trend in microelectronics to find substitutes for SiO₂ in gate dielectrics in MOS transistors. One candidate family of materials are the so called “high-k” materials, named for their high dielectric constant values, which is understood to be higher than the dielectric constants of SiO₂, e.g., typically above 4. To ascertain that TaSiN is compatible with high-k dielectrics, such as Al₂O₃, HfO₂, Y₂O₃, TiO₂, La₂O₃, ZrO₂, Silicates, and combinations of the above including the incorporation of nitrogen, FET devices were fabricated with TaSiN gates and HfO₂ gate dielectric, HfO₂ being a representative embodiment of high-k dielectrics.

FIG. 9 shows I_{d}—V_{g} curves in an FET using a TaSiN gate electrode and a high-k/Si oxinitride (SiON) gate dielectric. The CVD TaSiN films are stable on high-k dielectrics, such as HfO₂, with a low threshold voltage: Vt˜0.55 V, corresponding to the expected n-type Si like workfunction of TaSiN. In general advanced NMOS devices at ambient temperatures have threshold voltage values between about 0.15V and 0.55V. FIG. 9 also shows that a standard annealing, such as 450° C. forming gas anneal for a duration of 30 minutes, applied to the TaSiN—HfO₂ stack gives the usual improvement, yielding an excellent 76 mV/dec subthreshold slope for the device.

In the fabrication of CMOS circuits there are many processing steps and the gate material, in general, has to be able to withstand the temperatures involved during such processing. To evaluate the thermal stability of the TaSiN stacks, Medium Energy Ion Scattering (MEIS) experiments were conducted which show these stacks are stable at high temperatures up tp1000° C., with little or no interaction with the dielectric. The only change observed in the TaSiN layer may be some loss of hydrogen, which was in the TaSiN as a contaminant from the CVD process. This shows that the metallic TaSiN can be used in conventional CMOS processing.

Cross sectional Scanning Electron Microscope images were taken from the TaSiN layers on surfaces with topology. These images show that the CVD TaSiN process is conformal and may be used, for instance, to line trenches. This again is advantageous because it makes the TaSiN amenable for both a conventional “gate first” process, and a “gate last” replacement process. In the “gate first” process, the gate is deposited before the source and drain have been fabricated. In the replacement gate, “gate last” case, fabrication of the source and drain occurs before the final gate is deposited, usually in a trench resulting from the removal of a sacrificial gate.

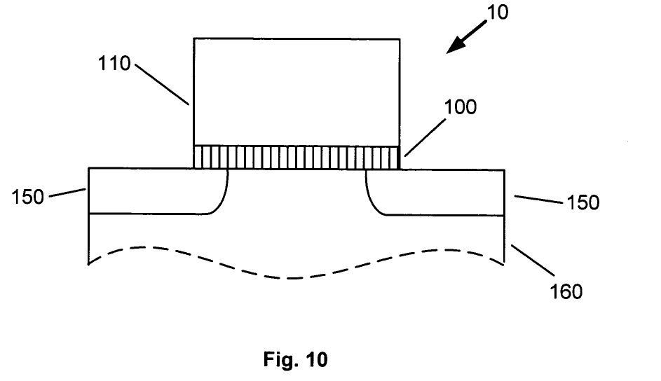

FIG. 10 shows a schematic cross sectional view of a semiconductor field effect device 10 having a metallic Ta—N compound, such as TaN or TaSiN gate. The gate dielectric 100 is an insulator separating the metallic gate 110 from a semiconductor body 160, with source/drain schematically indicated 150. The gate 110 comprises the metallic Ta—N compound, such as TaN and TaSiN. The gate may contain solely the Ta—N compound, or it may contain the Ta—N compound as part of a stacked layer structure. The gate insulator 100 can be any one of the insulating materials known to those skilled in the art, such as oxide, oxinitride, high-k material, or others, and in various combinations. A representative embodiment of the present invention is when the gate 110 is TaSiN, the FET device 10 is an NMOS with a high-k gate dielectric 100. However, the depicting of a semiconductor field effect device in FIG. 10 is almost symbolic, in that, although it actually shows an MOS device it is meant to represent any kind of field effect device. The only common denominator of such devices is that the device current is controlled by a gate 110 acting by its field across an insulator, the so called gate dielectric 100. Accordingly, every field effect device has a (at least one) gate, and a gate insulator. Thus the teaching of a new class of gate can impact every, and all, field effect devices. For instance, the body, can be bulk, as shown on FIG. 10, or it can be a thin film on an insulator (SOI). The channel can be a single one, or a multiple one as on double gated, or FINFET devices. The basic material of the device can also vary. It can be Si the mainstay material of today's electronics, or more broadly it can be a so called Si-based material, encompassing Ge alloys.

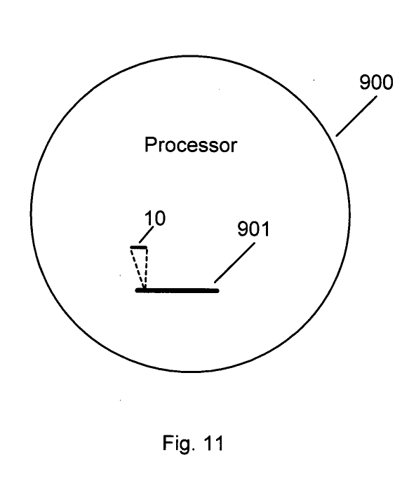

FIG. 11 shows a symbolic view of a processor 900 containing at least one chip which contains a semiconductor field effect device having a metallic Ta—N compound, such as TaN or TaSiN, gate. Such a processor has at least one chip 901, which contains at least one field effect device 10 having a TaN or TaSiN gate. The processor 900 can be any processor which can benefit from the TaN or TaSiN gate field effect device. These devices form part of the processor in their multitude on one or more chips 901. Representative embodiments of processors manufactured with the TaN or TaSiN gate field effect devices are digital processors, typically found in the central processing complex of computers; mixed digital/analog processors; and in general any communication processor, such as modules connecting memories to processors, routers, radar systems, high performance video-telephony, game modules, and others.

Many modifications and variations of the present invention are possible in light of the above teachings, and could be apparent for those skilled in the art. The scope of the invention is defined by the appended claims.

1-7. (canceled)

8. A semiconductor field effect device having a gate dielectric and a gate, wherein said gate comprises TaSiN disposed over said gate dielectric, wherein said TaSiN has the elemental ratio of N to Ta greater than about 0.9:1, and a workfunction between about 4.31 eV and 4.4 eV.

9-11. (canceled)

12. The field effect device of claim 8, wherein in said TaSiN the Si to Ta elemental ratio is between about 0.35:1 and 0.5:1.

13. The field effect device of claim 12, wherein said TaSiN has an a substantially amorphous material structure.

14. (canceled)

15. The field effect device of claim 8, wherein said gate dielectric has an equivalent oxide thickness of less than about 5 nm.

16. The field effect device of claim 15, wherein said gate dielectric has an equivalent oxide thickness of less than about 2 nm.

17. The field effect device of claim 8, wherein said gate dielectric comprises SiO₂.

18. The field effect device of claim 8, wherein said gate dielectric comprises a high-k dielectric material.

19. The field effect device of claim 8, wherein said device is a Si based MOS transistor.

20. The field effect device of claim 19, wherein said device is an NMOS transistor.

21. The field effect device of claim 20, wherein said NMOS transistor has a threshold voltage between about 0.36V and 0.45V.

22-32. (canceled)

33. A processor, comprising:
at least one chip, wherein said chip comprises at least one semiconductor field effect device having a gate dielectric and a gate, wherein said gate comprises TaSiN disposed over said gate dielectric, wherein said TaSiN has elemental ratio of N to Ta greater than about 0.9:1 and a workfunction between about 4.31 eV and 4.4 eV.

34. The processor of claim 33, wherein said processor is a digital processor.

35. The processor of claim 33, wherein said processor comprises at least one analog circuit

36. The field effect device of claim, wherein TaSiN has a resistivity below about 20 mΩcm.
